(19) United States
(12) Patent Application Publication
(10) Pub. No.: US 2022/0145447 A1
(43) Pub. Date: May 12, 2022

(54) FRACTIONING DEVICE

(71) Applicants: AGC GLASS EUROPE, Louvain-la-Neuve (BE); AGC INC., Chiyoda Ku (JP); AGC FLAT GLASS NORTH AMERICA, INC., Alpharetta, GA (US); AGC VIDROS DO BRASIL LTDA, Sao Paulo (BR)

(72) Inventors: Philippe ROQUINY, Moustier-sur-Sambre (BE); José FERNANDES, Le Roeulx (BE); Nicolas RIVOLTA, Gosselies (BE); Benjamine NAVET, Louvain-La-Neuve (BE); Amory JACQUES, Jambes (BE)

(73) Assignees: AGC GLASS EUROPE, Louvain-la-Neuve (BE); AGC INC., Chiyoda Ku (JP); AGC FLAT GLASS NORTH AMERICA, INC., Alpharetta, GA (US); AGC VIDROS DO BRASIL LTDA, Sao Paulo (BR)

(21) Appl. No.: 17/435,868

(22) PCT Filed: Feb. 25, 2020
(86) PCT No.: PCT/EP2020/054826

§ 371 Date: Sep. 2, 2021

(30) Foreign Application Priority Data
Mar. 4, 2019 (EP) 19160473.5

(51) Int. Cl. C23C 14/48; H01J 37/317; H01J 37/32

(52) U.S. Cl. CPC C23C 14/48; H01J 2237/31701; H01J 37/32357; H01J 37/3171

(57) ABSTRACT

A fractioning device for an ion implantation device with at least one fractioning wall, wherein the fractioning device is suitable for being inserted within a channel. The channel is configured to connect an ion source, which is at a first pressure p1 and a processing chamber, which is at a second pressure p2 in an ion implantation device.

### FIELD OF THE INVENTION

The present invention relates to a fractioning device and an ion implantation device equipped with a channel provided with said fractioning device, and a process of ion implantation carried out using said ion implantation device.

### BACKGROUND OF THE INVENTION

Ion implantation is a process by which ions of one element are accelerated into a substrate, thereby changing the physical, chemical, or electrical properties of the substrate. The technique thus consists of the bombardment of gaseous species (ionized or neutralized) and their implantation into the sub-micrometric layers of a substrate.

Ion implantation essentially requires an ion generation source, an electrostatic acceleration system, and a processing chamber under vacuum to house the substrate, all comprised within an ion implantation device.

Ions are generated by physical means in a chamber, using precursors appropriately converted to the vapor phase. The ion species are generated by an ion source, closely coupled to biased electrons for extraction of the ions into a beamline and most often to some means of selecting particular ion species for transport into the main accelerator section. The ion beam is thus created along a channel disposed between the ion source and the processing chamber, housing the substrate. The ion beam then reaches the surface of the substrate and processes the ion implantation. If the target surface of the substrate is larger than the ion beam diameter and uniform distribution of implanted dose is desired over the target surface, then some combination of beam scanning and substrate motion may be used, as appropriate.

The present invention does not relate to particle accelerators.

The ion source must be set under a certain vacuum pressure, while the processing chamber is set under a second vacuum pressure. In most instances, the first pressure in the ion source is lower than the second pressure in the processing chamber (p1<p2). In some instances, the first pressure in the ion source is higher than the second pressure in the processing chamber (p1>p2). In some instances, the first pressure in the ion source is equal to the second pressure in the processing chamber (p1=p2).

In the typical design of operations, the ion beam is directed towards the surface of the substrate, through a channel.

When there is a negative difference of pressure between the ion source and the processing chamber, it is required to adjust the setup of the equipment machine, such that the pressure differential is maintained throughout the operations. The lower first pressure in the ion source is indeed requiring constant pressure control, which may impact and disturb the second pressure in the processing chamber, which may tend to be disturbed by the vacuum pull of the ion source. Such vacuum pull may also prompt gaseous species to move upstream from the direction of the main beam, which is highly undesirable. These gaseous species moving upstream may indeed harm the ion source, or provoke loss of precision of the ion beam due to contamination of the source, contamination of the beam species, source instabilities. It can also dramatically reduce source lifetime (especially in the case of oxidation of the filament in a filament source).

There exist several ways to avoid such an upstream movement of gaseous species

1) increase the pumping efficiency in the processing chamber, such that the pressure is as close as possible as the pressure in the ion source, but this may involve the addition of more pumps to the processing chamber;
2) increase the length of the channel separating the ion source from the processing chamber the substrate in the treatment chamber, but such technical solution may be difficult to implement as it may impose a larger dimension of the ion implementation device, and also as it may require to re-focus the beam along the channel;
3) reduce the diameter of the channel, but this may negatively affect the amount of available ions from the beam and can also require costly beam focusing apparatus to master the beam diameter.

The several solutions listed above have main drawbacks in terms of space management, cost management, and efficiency management.

There thus still exists a need to increase the pressure differential between an ion source and a processing chamber in an ion implantation device, and to limit upstream movement of undesirable gaseous species, which do not pose the drawbacks of the above techniques.

When an ion beam reaches the surface of a substrate upon ion implantation, low energy electrons are emitted and the substrate tends to become positively charged. Generally, the net amount of positive charge delivered to the substrate is directly proportional to the beam current. In the case of a high current beam, the positive charge on the substrate tends to become quite high leading to surface voltage up to tens of volt and even kV depending on the impinging beam energy and the ability to discharge.

When the substrate surface is well grounded to the vacuum enclosure and free of dielectric layers, the charge mainly flows to ground. However, in some instances, the ability to discharge the electrostatic charges generated at the surface of the substrates is low as the charges cannot flow to the ground and charges may build up at the surface of the substrate.

Such a charge build-up creates problems. The electrostatic charge interacts with the beam and causes it to lose density, which is a disadvantage because variations in ion beam density result in a non-uniform implantation process and/or in a less efficient process. The surface of the substrate, while becoming positively charged, tends to repel the ions coming from the ion beam, such that the ion implantation is not homogeneously performed across the surface, and that ions initially implanted provoke a screen effect to the implantation of further ions. Pinholes may appear and/or ion implantation may be impaired.

In some instances, the beam diameter tends to expand upon coming closer to the substrate surface, as the ions all having the same electrical charge tend to repel one another. In those instances, the beam also loses in intensity and the ion implantation has a reduced homogeneity.

Also, electrostatic charge may discharge and create electric arc discharges which negatively impact the ion implantation process, by either imprinting shadows or inhomogeneities at the surface of the substrates, or by damaging the surface of the substrates.

The surface charge build-up during ion implantation process is thus preferably avoided.

Several solutions exist to such problems. One of these is to introduce a neutralizing charge, e.g electrons, to the surface of the substrate and/or to the beam before it contacts the substrate. One implementation of this method is to use a so-called electron shower to supply the neutralizing charge, or an electron flooding using negatively charged electrons. Another is to use plasma-generating sources to supply low energy electrons and positive ions. Both of these methods typically apply the neutralizing charge near where the beam contacts the substrate.

The patent application US 2016/0064260 A1 discloses an ion injection and a lens system for ion beam milling. A method and apparatus for performing ion etching on a semiconductor substrate are disclosed. A reaction chamber includes an ion source, a substrate support, and a hollow cathode emitter electrode having a plurality of hollow cathode emitter therein. The electrodes act on the ions such as to provide kinetic energy to the ion with respect to the substrate or attract positive ions in the plasma due to the potential difference on the electrodes. The purpose of the apparatus disclosed significantly deviates from the present invention, especially the role of electrodes.

U.S. Pat. No. 5,811,820 teaches parallel ion optics and apparatus for high current low energy ion beams. A device includes an ion source, ion capture, and storage ion optics, mass selection ion optics, neutral trapping elements, extraction ion optics, beam neutralization mechanisms, and substrate. The ion-processing unit includes planar electrode sheets having holes therethrough, which define the ion-conducting channels. Varying radio frequency voltages may be applied to the electrode sheets to generate inhomogeneous RF fields for manipulating ions in the ion-conducting channels. Both prior art documents disadvantageously disclose electrodes to manipulate ions that pass through them.

No one of these prior art documents teaches to achieve a homogenous ion beam for implantation, reduction or cancellation of the charge build-up for a reduced repellency of the ions in the beam or no loss in intensity upon the passage through the fractioning device.

Electron showers, however, typically supply a large number of high energy electrons which themselves contribute to the charging of the substrate surface.

Plasma sources, which typically supply a higher proportion of low energy electrons and ions than do electron showers, not only better neutralize the beam and the surface charge but also contribute less to negative charge buildup on the substrate. When using a plasma source, however, a large plasma density is required to neutralize the beam. The required density can increase the pressure in the vacuum enclosure and degrade the efficiency of the implantation process. Moreover, a uniform and dense plasma are necessary.

These solutions require the addition of electrons and ions in a vacuum atmosphere, which may increase complexity of the processing conditions.

### SUMMARY OF THE INVENTION

The present invention relates to a fractioning device for an ion implantation device comprising at least one fractioning wall, wherein the fractioning device is suitable for being inserted within a channel. The channel is configured to connect an ion source, which is at a first pressure p1 and a processing chamber, which is at a second pressure p2 in an ion implantation device.

The present invention also relates to an ion implantation device equipped with a channel provided with the said fractioning device. An average transversal cross-sectional length of the fractioning device is at least 10% of an internal perimeter of the fractioning device.

Also a length of the fractioning device is preferably not more than 80% of the length of the channel.

Also provided is a process for ion implantation carried out using the present ion implantation device.

Last provided are the use of a fractioning device in an ion implantation device, for maintaining a pressure differential between an ion source and a processing chamber of said ion implantation device, and the use of a fractioning device to reduce charge build-up at the surface of the substrate during an ion implantation process.

The purpose of the present invention is to allow for a high pressure differential without negatively impacting the size of the device nor the efficiency of the ion source, nor the ion beam intensity.

The present invention, therefore, aims at providing a fractioning device useful in an ion implementation device to limit the undesired movement of the gaseous species against the ion beam generated by the ion source, from a higher pressure zone towards a lower pressure zone. The undesired movement may be an “upstream” movement if the pressure in the ion source is less than the pressure in the processing chamber (p1<p2), that is the upstream movement is in a direction opposite to that of the ion beam. The undesired movement may be a “downstream” movement, when the pressure in the ion source is greater than the pressure in the processing chamber (p1>p2), that is the downstream movement is in the same direction as that of the ion beam. The present fractioning device is thus an obstacle to gaseous displacement between the processing chamber and the ion source, through the connecting channel, of an ion implantation device, when there exists a pressure differential between said processing chamber and ion source.

The fractioning of an ion beam is usually avoided, to ensure integrity and intensity of the ion beam, however, a fractioning device installed in an ion implantation device as presented herein allows for pressure control with minimal contamination.

Surprisingly, the inventors have shown that the present fractioning device allows for an effective control of charge build-up at the surface of substrates during an ion implantation process, and as such, the present fractioning device may be useful as charge neutralizer in the above-described configurations.

### FIGURES

FIG. 1.a-g: fractioning device of different design

FIG. 2.a and b: a: schematic ion implantation device comprising a first chamber (1), a second chamber (2) and a channel (3), with optional valves (4) and (5); b: lateral view of fractioning device having three fractioning walls (6,7,8), intersecting at the center point of the inner section of the channel (3)

FIG. 3.a to c: fractioning device of a channel having an inner section of square shape with fractioning walls parallel to the sides of the square

FIG. 4: optimal ion flow from source A, within external walls B1 and B2, representing the inner section of the channel, with 0 or 1 or (2m+1) number of fractioning walls, parallel to the channel walls B1 and B2.

### DETAILED DESCRIPTION OF THE INVENTION

The present invention thus relates to a fractioning device for an ion implantation device comprising at least one fractioning wall, inserted within a channel connecting an ion source, which is at a first pressure p1 and a processing chamber, which is at a second pressure p2 in an ion implantation device, wherein the average transversal cross-sectional length (ATCSL) of the at least one fractioning wall of the fractioning device is at least 10% of the internal perimeter of said channel.

The length of the fractioning device is preferably not more than 80% of the length of the channel.

The term “channel” used herein refers to the conduit, or tube, connecting the ion source, which is at a first pressure p1 and the processing chamber, which is at a second pressure p2 in an ion implantation device. The fractioning device is thus inserted within the internal section of the channel.

The channel has an inner cross-section, which allows the passage of the ion beam within the length of its internal cross-section, from the ion source to the processing chamber. The channel may have a circular or non-circular internal cross-section. That is, the internal section of the channel may be of round shape, or square shape, or rectangular shape, or triangular shape, or polygonal shape, or shapes combined therefrom. The direction of the ion beam is substantially the same as the axis of the center point of the channel, throughout the channel length.

The internal cross-section of the channel has a perimeter, that is, the channel has an internal perimeter. The internal perimeter of the channel may be the same over the length of the channel or may increase or decrease along the length of the channel. That is, the channel may have a longitudinal inner shape that is tubular or conical. In most instances, the internal perimeter of the channel is the same over the length of the channel. Otherwise, the average internal perimeter of the channel is considered herein, that is, the average of the perimeters of the channel along its length.

The channel may have a length of from 5 to 200 cm, alternatively from 5 to 150 cm, alternatively from 5 to 100 cm, alternatively from 5 to 80 cm.

The fractioning device comprising at least one fractioning wall is disposed such that the average transversal cross-sectional length (ATCSL) of the fractioning device comprising at least one fractioning wall is at least 10% of the internal perimeter of said channel. Alternatively, the average transversal cross-sectional length of the fractioning device comprising at least one fractioning wall is at least 20% of the internal perimeter of said channel, alternatively at least 30%.

The at least one fractioning wall of the fractioning device may be placed along the center point of the internal section of the channel, or it may be placed at any distance from the center point of the internal section of the channel. The at least one fractioning wall of the fractioning device is preferably placed along the center point of the internal section of the channel. The fractioning device with at least one fractioning wall will provide at least one guide to the ion beam. The fractioning device with at least one fractioning wall is thus providing the internal section of the channel with at least two compartments. The number of compartments increases as the number of fractioning walls increases.

The fractioning device comprising at least one fractioning wall is thus constructed so as to fraction or divide the internal section of the channel through which the ion beam is directed, into 2 or more compartments. The ion beam is fractioned along the fractioning device by passing through it. The so-fractioned ion beam maintains the original direction of the unfractioned ion beam. That is, the fractioning device is not intended to modify the trajectory of the ion beam and is also not intended to modify the trajectory of the resulting fractions of said ion beam.

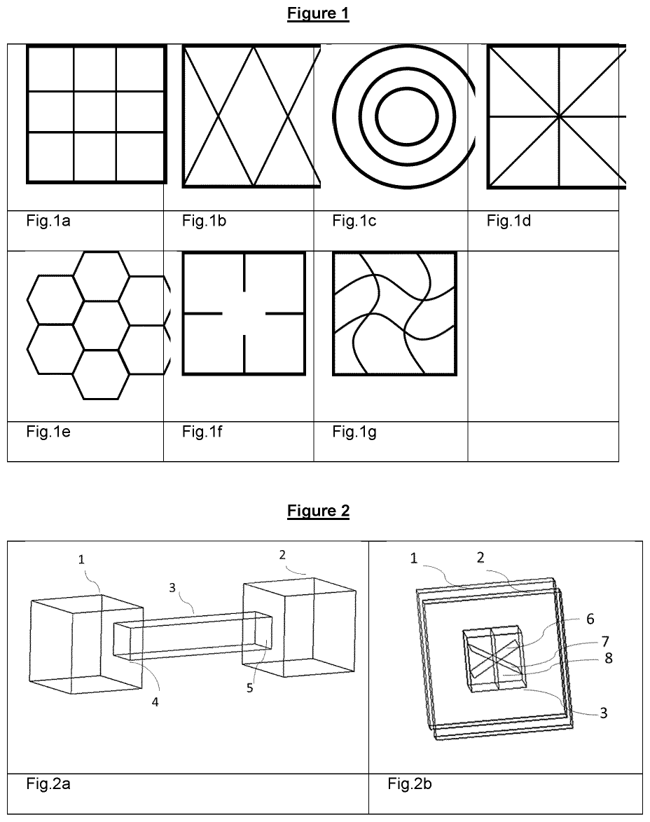

When there is more than one fractioning wall, the multiple fractioning walls may intersect inside or outside the internal section of the channel, or they may not cross. When the multiple walls intersect, they may do so in the center of the internal section of the channel (FIG. 1d), or they may intersect at any other point (FIG. 1a, b, e, g), or disposed in manner such that they intersect in a virtual line (FIG. 1f). When the multiple walls do not intersect, they may be parallel, or substantially parallel, or concentric (FIG. 1c).

Subsequently, the fractioning device divides the ion beam in multiple compartments, or, as may be otherwise stated, the fractioning device guides the ion beam as multiple fractioned ion beams. There is however no interaction with the ion beam. When the fractioning device is of circular shape, a single fractioning wall will provide for 2 compartments of the ion beam; two fractioning walls having an intersection will divide the ion beam in 4 compartments; three fractioning walls having a common intersection will divide the ion beam in 6 compartments.

When the fractioning device is of square shape, a single fractioning wall will provide for 2 compartments of the internal section of the channel; two parallel fractioning walls will divide the internal section of the channel in 3 compartments; three parallel fractioning walls will divide the internal section of the channel in 4 compartments. Adding an intersecting wall to any of the walls parallel combinations will increase the number of compartments within the internal section of the channel.

When there are at least two walls in the fractioning device, the average length of the fractioning device takes into account all walls comprised in said fractioning device. In such instances, the average transversal cross-sectional length (ATCSL) of the fractioning device is at least 10% of the internal perimeter of said channel, alternatively at least 20%, alternatively at least 30%. The average transversal cross-sectional length (ATCSL) of the fractioning device may be greater to the internal perimeter of the channel.

Various examples of fractioning devices are provided in FIG. 1, where the fractioning walls are set according to the internal section of the channel, with the number of walls, the number of compartments indicated, illustrative perimeters and illustrative average transversal cross-sectional length (ATCSL) of the fractioning device in Table 1.

In some instances, the fractioning walls are only partial walls, that is, the partial wall is not placed across the entire cross-section of the channel, but only a part of the inner cross-section of the channel. In those instances, the ion beam is not divided into compartments but remains only guided through its passage through the channel along the partial fractioning walls (FIG. 1f).

TABLE 1

| | Number of | Number of | | |
|---|---|---|---|---|
| Fractioning | fractioning | compart- | Perimeter | ATCSL |
| device | walls | ments | (cm) | (cm) |
| FIG. 1a | 4 | 9 | 10 | 10 |
| FIG. 1b | 4 | 7 | 10 | 11 |
| FIG. 1c | 2 | 3 | 7.5 | 4.7 + 3.1 = 7.8 |
| FIG. 1d | 4 | 8 | 10 | 12.2 |
| FIG. 1e | Honeycomb | 7 | 10 | 6.7 |
| | (9) | | | |
| FIG. 1f | 4 (partial) | 1 | 10 | 3 |
| FIG. 1g | 4 | 9 | 10 | 12.5 |

The present fractioning device may be located at any height inside the channel. That is, the fractioning device may be located at or near the entry of the channel, in the vicinity of the ion source, or the fractioning device may be located at or near the exit of the channel, in the vicinity of the processing chamber, or the fractioning device may be located at or near the center height of the channel, in or near the middle between the ion source and the processing chamber.

The length (L) of the fractioning device is not directly critical to its functioning. The length of the fractioning device is different from the average transversal cross-sectional length (ATCSL). The length L is the dimension of the fractioning device within the length of the channel, in the direction of the ion beam. The average transversal cross-sectional length (ATCSL) is the dimension of the fractioning device across the channel, perpendicular to the ion beam, that is, the sum of the cross-sectional measure of the one or more fractioning walls in the path of the ion beam.

The length of the fractioning device is preferably not more than 80% of the length of the channel. In some instances the length of the fractioning device may be 100% of the length of the channel or the length of the fractioning device may be less than the length of the channel, that is, the length of the fractioning device may be 80% of the length of the channel, or may be 60% of the length of the channel, or may be 40% of the length of the channel, or may be 20% of the length of the channel, or may be 5% of the length of the channel. Charge neutralization may be effected when the length of the fractioning device is less than 5% of the length of the channel.

In some instances, the length of the fractioning device may be greater than the length of the channel, that is, the length of the fractioning device may be 120% of the length of the channel, or may be 110% of the length of the channel.

In some instances, the fractioning device, irrespective of its length in comparison with the length of the channel, may protrude out of the channel into the processing chamber, through gate valve B. Such protrusion into the processing chamber may range of from 1 to 10 cm, alternatively of 1 to 8 cm.

The channel may be equipped with one or more fractioning devices, at different heights within the channel, to increase the effect, as long as there is only limited to no negative impact on the ion beam intensity, in comparison with the intended dose. The variation should be less than 50% of the intended dose to treat the substrate; alternatively, variation should be less than 30% of the intended dose; alternatively, variation should be less than 10% of the intended dose.

When the length of the fractioning device is equal to 80% the length of the channel, there may only be 1 fractioning device within the channel. When the length of a fractioning device is 40% of the length of the channel, there may be 2 fractioning devices within the channel. The channel may also comprise two or more fractioning devices of different lengths. For example, there may be 2 fractioning devices within the channel, one having a length=60% of the length of the channel, and a second having a length 40% of the length of the channel.

There is thus no major limit to the options of the disposition of the fractioning walls in the fractioning device, as long as the beam intensity is not negatively impaired. Such negative impact will be observed if the ion beam current is reduced by more than 30% at the processing chamber, alternatively by more than 20%, alternatively by more than 10%.

The material composing the fractioning device will be advantageously chosen or treated to reduce or avoid sputtering during exposure to the ion beam. There is thus no major limit to the options of the composition of the fractioning device, as long as the ion-implanted surface of the substrate is not contaminated. The absence of contamination will be observed if the implanted species, as measured on the substrate, contain less than 10% of ions originating from the fractioning device, alternatively less than 5%, alternatively less than 1%, alternatively less than 0.1%, alternatively less than 0.01%.

The bulk material of the fractioning device may be based on graphite, or a metal or a metal alloy, comprising at least 50% by weight of a metal or metal alloy, selected from the group consisting of the following metals Al, Cu, Zn, Mn, Ti, Ni, Cr, Fe, Mo, or of the alloys of one or more of the metals Al, Cu, Zn, Mn, Ti, Ni, Cr, Fe, Mo. The bulk material of the fractioning device may comprise at least 50% by weight of graphite or stainless steel.

Typically, the bulk materials will be provided with sputtering reduction coatings. Such coating may be conductive, having a low resistivity, in particular, less than 5×10⁷ ohm cm. Examples of sputtering reduction coatings include boron carbide, silicon oxide or carbide or nitride, aluminium carbide, zirconium oxide or carbide, titanium oxide or carbide, molybdenum oxide or carbide, niobium oxide or carbide, yttrium oxide or carbide, magnesium oxide, tin oxide, ceramic, tungsten carbide, tungsten oxide, hafnium oxide, tantalum oxide, carbon (like pressed graphite), chromium carbide or combinations of these materials.

The fractioning device may comprise at least one material selected from graphite, stainless steel, boron carbide, silicon oxide or carbide or nitride, aluminium carbide, zirconium oxide or carbide, titanium oxide or carbide, molybdenum oxide or carbide, niobium oxide or carbide, yttrium oxide or carbide, magnesium oxide, tin oxide, ceramic, tungsten carbide, tungsten oxide, hafnium oxide, tantalum oxide, carbon (like pressed graphite), chromium carbide or combinations of these materials.

Alternatively, the fractioning device may comprise at least one material selected from stainless steel, zirconium oxide or carbide, titanium oxide or carbide, tungsten carbide, tungsten oxide, or combinations thereof.

In some instances, although not preferred, the fractioning device may be heated. In those instances, it may intercept free electrons and contribute to the charge neutralization before the beam reaches the surface of the substrate to be processed through ion implantation.

The present invention provides for an ion implantation device comprising:

a. an ion source is at a first pressure p1 for generating an ion beam,
b. a processing chamber is at a second pressure p2 for housing a substrate,
c. a channel connecting the ion source and the processing chamber, said channel having an internal cross-section and allowing the passage of the ion beam within said internal cross-section,
wherein the channel comprises at least one fractioning device of the present invention within its internal cross-section along at least part of the length of its internal cross-section.

The present invention thus provides for an ion implantation device comprising:
a. an ion source configured to be operated at a first pressure (p1) suitable for generating an ion beam,
b. a processing chamber configured to be operated at a second pressure (p2) suitable for housing a substrate,
c. a channel configured to connect the ion source and the processing chamber, wherein the channel is configured to have an internal cross-section and to allow the passage of the ion beam within the internal cross-section, and
   wherein the channel comprises at least one fractioning device of the present invention within its internal cross-section along at least part of the length of the internal cross-section.

Typically, pressures p1 and p2 are low pressures, usually vacuum pressures, when the ion implantation device is set to function. Vacuum may be defined as a space absolutely devoid of matter, or a space partially exhausted (as to the highest degree possible) by artificial means (such as an air pump), below atmospheric pressure (Merriam-Webster, 2018). The interest of vacuum is that the removal of particles allows for certain processes to be carried out in absence of any disrupting matter. This lack of matter allows ion to travel longer distance by avoiding collision or other deflecting processes with residual atom or molecules.

Vacuum may typically be classified in rough vacuum, having a pressure ranging of from atmospheric pressure to 10⁻¹ Pa (=10⁻³ mbar); high vacuum, having a pressure ranging of from 10⁻¹ to 10⁻⁶ Pa (=10⁻³ to 10⁻⁸ mbar); and ultrahigh vacuum having a pressure ranging of from 10⁻⁶ to 10⁻¹⁰ Pa (=10⁻⁸ to 10⁻¹² mbar). Therefore, a reduction of pressure in a defined space is indicative of the reduction of gaseous matter present in said defined space.

The ion source may be a hot filament source, where electrons are thermionically emitted from a current heated filament and serve to ionize a gaseous species injected in the source enclosure. This kind of source is then driven by current and voltage on the electron emission of the filament as well as by the available quantity of gas available for ionization (gas pressure). The ions generated are then extracted and attracted by a high voltage and form an ion beam that is then emitted and guided in the direction of the processing chamber, through the channel.

The ion source may be an Electron Cyclotron Resonance ion source, known as an ECR source. This ECR source delivers an initial beam of ions, with parameters for ion species relative to the pressure and nature of the gas feeding the enclosure, as well as the excitation current and voltage. The chamber of the source contains a hot plasma composed of a mixture of magnetically confined ions and electrons. The ion beam is emitted and guided in the direction of the processing chamber, through the channel.

In both ECR and filament sources cases, the ions can be extracted from the chamber through an opening and then accelerated. To produce gaseous ions, the chosen gas is introduced into the source in sufficient quantity to bring the ion beam to the required intensity, for example, oxygen (only for the ECR source), nitrogen, neon, argon, helium, etc.

A typical ECR ion implantation source may simultaneously produce single charge and multicharge ions. Multicharge ions are ions carrying more than one positive charge, single charge ions carry one single positive charge. Typically, an ECR ion source may deliver mono- and multi-charged ions, which makes it possible to implant multi-energy ions simultaneously at the same extraction voltage. In this way, a more or less well-distributed implantation profile can be obtained simultaneously throughout the treated thickness of the substrate, possibly at different depths from the surface of the substrate.

Examples of ions that may be implanted by an ECR source include one or more of the ions of N, H, O, F, C, He, Ne, Ar, Xe, and Kr. The single charge and multicharge ions generated simultaneously by the ion source make up the ions of the beam. Sources gases include N₂, He, O2, CO2, Ar, H₂, F₂, CF₄, CH₂, CH₄ and mixtures of these.

The first pressure p1 at the ion source typically ranges of from 0.1×10⁻³ to 10⁻³ Pa (10⁻⁵ Torr), alternatively of from 0.1 to 0.7×10⁻³ Pa, alternatively of from 0.2 to 0.6×10⁻³ Pa.

The dosage of said ions that are implanted by an ion implantation device as described herein may be comprised between 10¹⁴ ion/cm² and 10²² ion/cm², alternatively between 10¹⁴ ion/cm² and 10¹⁸ ion/cm², alternatively between 10¹⁵ ion/cm² and 10¹⁸ ion/cm².

The acceleration voltage may range of from 5 kV to 1000 kV, alternatively of from 5 kV to 200 kV, alternatively of from 8 kV to 100 kV, alternatively of from 10 kV to 60 kV, alternatively of from 12 to 40 kV, alternatively at 35±2 kV.

The beam power may be set at a value ranging of from 1 W to 1 kW, alternatively of from 20 W to 750 W.

The processing chamber housing the substrate may be equipped with various elements, such as substrate holder (planar or non-planar), substrate moving system (linear or rotating), precision positioning device, Faraday cup, vacuum pump, opening enclosure, possibly connecting enclosures, possibly cooling circuits, etc. Any suitable processing chamber may be used in conjunction with the presently claimed ion beam fractioning device.

The pressure p2 in the present processing chamber will usually have a starting point at atmospheric pressure, at about 1.01×10⁵ Pa (101325 Pa). When vacuum is set in the processing chamber, that is, when the pressure is no longer atmospheric pressure, the pressure may range of from 10⁻⁸ to 10⁻¹ Pa, alternatively from 10⁻⁶ to 10⁻³ Pa, alternatively from 10⁻⁵ to 10⁻³ Pa, alternatively of from 10⁻⁵ to 10⁻⁴ Pa.

Vacuum in the processing chamber is effected by use of at least one standard primary pump and turbopump, or other pump type allowing to reach the process pressure. More than 1 pump may be used to provide for vacuum conditions in reduced amount of time. In some instances, more than one pump may be used, that is, 2, 3 or more.

The ion implantation device may be equipped with a gate valve A between the ion source and the channel (for example located in position 4 or 5 of FIG. 2a), and/or with a gate valve B, between the channel and the processing chamber (for example located in position 5 or 4 of FIG. 2a, depdending on the position of gate valve A). The respective gate valves allow for the sealing of either one of the ion source or the processing chamber or both, from the channel.

In some instances, the ion source may be equipped by a ceramic section into the channel, through gate valve A, said channel being connected to the ground, as opposed to the high tension imposed on the ion source itself. Said ceramic section may be equipped with a ceramic fractioning device. In those instances, the fractioning device may be composed of at least two individual fractioning devices, where a first fractioning device comprises ceramic, located in the chamber housing the ion source and a second fractioning device in the channel section as described above.

In some instances, gate valve A may be closed to isolate the ion source and, for example, provide maintenance while not disrupting the pressure in the processing chamber. In such instances, gate valve B may also be closed or may remain open.

For example, gate valve B may be closed when the processing chamber needs to reach the atmospheric pressure, or when the processing chamber undergoes degassing of the substrate or any other instance where p2 is modified “drastically”, sealing the ion source at its initial vacuum pressure. In such instances, gate valve A may also be closed or may remain open.

The channel may be equipped with one or more vacuum pumps. In some instances, an additional pump located at the channel may assist in maintaining the pressure differential.

The pressure distribution in the channel will typically vary within a range comprised between p1 and p2, when there are no valves or that the present valves are open. The pressure distribution in the channel will depend on the pressures p1 and p2, but will also depend on an optional pumping rate within the channel. The pressure distribution in the channel will also depend on its geometry, that is, its length, diameter/perimeter, shape, etc.

When the first pressure p1, at the ion source, is less than the second pressure p2, in the processing chamber, the residual gasses present in the processing chamber may be prompted to go upstream in the channel and impair the stability of the first pressure p1. The presence of the fractioning device is intended to reduce said undesired movement of gaseous species, and to maintain the pressure differential between these 2 pressures p1 and p2 while leaving the directional accelerated species from the beam travel through the channel.

The purpose of controlling the quality of the pressure p2 is to ensure the outgassing of a substrate will not impair the ion implantation process on the substrate, and will also not destabilize the ion source.

In other instances, the first pressure p1, at the ion source is greater than the second pressure p2, in the processing chamber.

The charge neutralization may be effected whenever p1>p2, p1<p2, or when p1=p2.

An ion beam may be characterized by a useful angle, while a channel may be characterized by its conductance. Both the useful angle and the conductance may be impacted by the presence of a fractioning device with at least one fractioning wall. The impact on the conductance of the channel may or may not be linked to the impact on the useful angle.

As such, a relationship may be established between the number of fractioning walls in the fractioning device and the useful angle of the ion beam and another relationship may be established between the number of fractioning walls in the fractioning device and the conductance in the channel, depending on the geometry of the internal section of the channel. A compromise may thus be established to optimize the number of fractioning walls within the fractioning device.

In situations where the internal section of the channel is of square shape, and in the assumption that the path of the ion beam is linear from the source to the substrate, the useful angle and the conductance may be calculated as follows.

The useful angle of the ion beam is defined as the angle of incidence of the ion beam as generated by the ion source, without any inflection, minus the lost portion of the beam due to the fractioning walls (0 to 2m+1), as in FIG. 4, where the calculation is made for a two-dimensional space from the ion source, perpendicular to the substrate. The source will indeed generate a certain ion beam of certain voltage and dosage, within a defined angle 2a. The lost portion β of the angle 2a is defined as the sum of the lost portions due to each fractioning wall m.

The useful angle may be an indication of the available ion beam reaching the surface of the substrate, impacting the dosage of implantation, and the duration of the ion implantation process.

The useful angle θ may be calculated as follows:

$$\begin{matrix}Θ = 2 ( α - {\sum }_{i = 0}^{m} {β}_{i} ) . \\ With , & Formula I \\ α = a tan ( \frac{r}{{L}_{1} + {L}_{2}} ) \\ and & Formula II \\ {β}_{i} = a tan ( \frac{{L}_{1} + {L}_{2}}{i \frac{r}{m + 1}} ) - a tan ( \frac{{L}_{1}}{i \frac{r}{m + 1}} ) . & Formula III\end{matrix}$$

The conductance is defined as the ability for a channel to allow a flow of non-accelerated gas species, where the movement of the gas species is a stochastic displacement. On the contrary, an accelerated ion beam is typically directional as it is considered to adopt a theoretical ballistic movement. The conductance is calculated for a tri-dimensional space, taking into account the shape of the channel.

$$\begin{matrix}C = \frac{16}{3} {( \frac{R T}{2 π M} )}^{1 / 2} \frac{{S}^{2}}{a L} K & Formula IV \\ C = σ \frac{{S}^{2}}{a} & Formula V\end{matrix}$$

with
C=conductance channel (m³/s)
R constant of a perfect gas
T gas temperature
M gas molar mass
S channel surface
a channel perimeter
L channel length
K constant dependent on shape factor (=1 for a circle, =1,108 for a square)

The conductance herein is an indication of the ability of the channel, equipped with the fractioning device, to decrease the stochastic motion of non-accelerated gaseous species. A lower conductance may thus be indicative of the reduced movement of undesired non-accelerated gaseous species.

Typically, charged ions display a ballistic motion when accelerated by a high voltage, while uncharged ions do not undergo such a ballistic motion, but only stochastic displacement, which should be decreased for non-accelerated gaseous species.

The ion implantation device may further comprise one or more of controlling apparatuses. These are used to provide control and data information about the ion source, the ion beam, the ion distribution, the location and position of the substrate in the processing chamber, the first pressure in the ion source, the second pressure in the processing chamber and so on. Such controlling apparatuses may include a mass spectrometer suitable for filtering the ions according to their charge and mass; a profiler, whose purpose is to analyse the intensity of the beam in a perpendicular intersecting plane; a current transformer, which continuously measures the intensity of the ion beam without intercepting it; a shutter, which can be a Faraday cage, the purpose of which is to interrupt the trajectory of the ions at certain times, for example when the substrate is being displaced without being treated; a numerical control machine, for positioning and moving the substrate in the processing chamber.

The ion implantation device is intended to provide for ion implantation of a substrate.

The present invention thus provides for a process for ion implantation on a substrate comprising the steps of

a. Providing for a substrate,
b. Providing for a device according to the above,
c. Proceeding to the ion implantation of the substrate.

Examples of substrates include those substrates comprising glass; sapphire; alumina; polymers; elastomers; resins; metals, metal oxides or metal alloys; composite materials; ceramics; stones; or powders or mixtures of these or other material. The substrate may be conductive, or non-conductive.

Examples of polymers include polymethylmethacrylate, polyurethane, plastic, polyethylene, polypropylene, and powders, mixtures or composites thereof.

Examples of glass include clear glass or colored glass, obtained by float or other manufacturing methods. The glass may be soda lime glass, aluminosilicate glass, borosilicate glass, boroaluminosilicate glass, or any other glass composition. The glass may be in the shape of flat glass or curved glass, or the glass may be a container shape, such as bottle, drinking glass, or else.

Sapphire substrates (or corundum) mainly comprise aluminium oxide, potentially colored with elements including, but not limited to, iron, titanium, vanadium, chromium. They may be natural or synthetic sapphire substrates.

The substrate may have varying shapes, from planar to non-planar surfaces. Planar surfaces include flat and/or convex and/or concave surfaces. Non-limiting examples of planar substrates include glass pieces, watch glasses, metal sheets, polymer sheets, or else.

Non-limiting examples of non-planar surfaces include those with holes, with indents, with generally uneven surfaces, or with substantially spherical surfaces. Non-limiting examples of non-planar substrates include jewelry accessories (such as jewels, pearls, gems and stones), engineering accessories (such as pistons, valves, bolts, nails, screws, needles, pins, links, balls, or else), electronic accessories (such as chips, electronic connectors, or else), polymeric accessories (such as phone covers, earplugs, wire encapsulants, headphones, keyboard keys, computer covers, or else), medical accessories (ortheses, prostheses, appliances, etc.), sport accessories (ping pong ball, golf ball, snooker ball, or else), and others.

Further examples of non-planar surfaces include substrates in powder form, that is, particulate matter. Such powder forms of substrates may typically be arranged as a powder layer on a planar support for ease of handling or may be arranged on a vibrating pan on a moveable substrate holder. The support may be moved or the powder layer may be re-arranged according to the end use and to the substrate holder, and if several passes of the ion implantation process are required. The powder form is considered non-planar, herein, in that the powder as spread out on the support surface may provide for an uneven surface.

The substrate is typically not polarized.

The substrate may have a thickness of from 0.01 to 25 mm. For example, a glass sheet may have a thickness of from 0.1 to 8 mm, alternatively of from 0.1 to 6 mm, alternatively of from 0.1 to 2.2 mm. In other applications, the substrate may have a thickness of from 10 μm to 100 μm, alternatively of from 50 μm to 100 μm. Powders include those having a particle size ranging of from 0.001 μm to 1 mm, alternatively of from 0.01 to 0.7 mm.

The implantation depth of the substrate starts at the substrate surface and reaches down to a depth d, into the substrate, where typically, d is comprised within a range of from 10 to 2000 nm, alternatively of from 10 to 1000 nm, alternatively of from 10 to 700 nm, alternatively of from 10 to 500 nm. The implanted ions are spread between the substrate surface and the implantation depth. The implantation depth may be adapted by the choice of implanted ion, by the acceleration energy and varies to a certain degree depending on the substrate.

For a given total ion dosage, a narrow depth distribution is obtained when only simple charge ions are implanted and a wider depth distribution is obtained when simple charge and multicharge ions are implanted simultaneously. That is, because of their higher energy, ions carrying a higher charge will be implanted deeper into a substrate than ions carrying a lower charge. In some instances, the implantation depths may be distributed in a ladder-type manner, where a first ion species reaches a first depth, and a second ion species reaches a second depth, the latter either less or more deep than the first depth.

After completion of the ion implantation procedure, the concentration of invading ions in the substrate may be determined by secondary ion mass spectroscopy (SIMS) or nuclear analysis methods like Rutherford Back Scattering (RBS), Nuclear Reaction Analysis (NRA) or ERD (Elastic Recoil Detection).

The implantation of ions in a substrate will typically modify its surface properties, such as reflectance or surface hardness.

The present invention provides for the use of a fractioning device in an ion implantation device comprising an ion source, generating an ion beam is at a pressure p1, and a processing chamber housing a substrate is at a pressure p2, to increase the pressure difference between p1 and p2.

The present fractioning device may also be used to reduce charge build-up at the surface of substrates during an ion implantation process, such that the surface can be treated homogeneously.

The reduction or cancellation of the charge build-up allows fora reduced repellency of the ions in the beam, and in an increase in homogeneity of the beam reaching the surface of the substrate. Additionally, the beam does not lose in intensity upon the passage through the fractioning device.

The present invention provides for a first method to increase the pressure difference between an ion source at a pressure p1 and a processing chamber housing a substrate at a pressure p2, in an ion implantation device comprising:

a. an ion source, which is at a first pressure p1 for generating an ion beam,
b. a processing chamber, which is at a second pressure p2 for housing a substrate,
c. a channel connecting the ion source and the processing chamber, said channel having an inner cross-section and allowing the passage of the ion beam within at least part of the length of its inner cross-section,
wherein the channel comprises at least one fractioning device within its inner cross-section along at least part of the length of its inner cross-section.

The present invention provides for the use of a fractioning device in an ion implantation device according to the above comprising:
a. an ion source configured to maintain a first pressure (p1) suitable for generating an ion beam,
b. a processing chamber configured to maintain a second pressure (p2) suitable for housing a substrate, and
c. the fractioning device configured to increase the pressure difference between the first pressure and the second pressure.

The present invention provides for a second method to reduce charge build-up at the surface of a substrate, in an ion implantation device comprising: a.

an ion source, which is at a first pressure p1 for generating an ion beam,

b. a processing chamber, which is at a second pressure p2 for housing a substrate,
c. a channel connecting the ion source and the processing chamber, said channel having an inner cross-section and allowing the passage of the ion beam within at least part of the length of its inner cross-section,
wherein the channel comprises at least one fractioning device within its inner cross-section along at least part of the length of its inner cross-section.

The present invention provides for the use of a fractioning device in an ion implantation device according to the above comprising:
a. an ion source configured to operate at a first pressure suitable for generating an ion beam
b. a processing chamber configured to operate at a second pressure suitable for housing a substrate, and
c. operating the fractioning device in order to reduce charge build-up at the surface of the substrate during an ion implantation process.

### EXAMPLES

Simulations of the conditions of use of an ion implantation device have been conducted, where the pressure p1 in the ion source is typically lower than the second pressure p2 in the processing chamber, in the vicinity of the substrate to be implanted. In such conditions of pressure differential, it may be difficult to ensure proper vacuum conditions in the machine at different locations of the device during the processing.

The present simulation technique allows for demonstrating that the presence of the fractioning device reduces the pressure inside the channel, such that a reduced amount of undesired gaseous species is able to move upstream the ion beam emitted by the ion source, within said channel. Indeed, as discussed above, a reduction in pressure is indicative of the reduction in gaseous matter in the defined space. The present examples indicate that the reduction in pressure ensures the reduction of unwanted gaseous species in the trajectory of the ion beam. The absence of such species ensures quality of the vacuum in the ion source, prevents the pollution of the channel and/or of the ion source. The gain may be found in cost management (reduced maintenance, reduced time to reach vacuum), space management (the channel did not require any size change), etc.

Simulation parameters were as follows: Direct simulation Monte Carlo (DSMC), Particle in a cell Monte Carlo method (random motion, stochastic motion), Fraunhofer IST.

### Example 1

A configuration featuring a first chamber (1), a second chamber (2) and a channel (3) connecting the two chambers were designed, in FIG. 2a. The inner section of the channel was of square shape, with fractioning walls crossing at the center of the square (FIG. 2b: with 3 fractioning walls). The number of fractioning walls was varied to indicate impact on the pressure. The channel's inner dimensions were 0.5×0.1×0.1 m³, and internal perimeter of 0.4 m (=4×0.1 m).

The second chamber representing a process chamber was set at a pressure of 0.5 Pa, and the pressure in the first chamber representing a source chamber, was measured, with a pump operated at a pumping speed of 250 l/s.

The reduction of pressure is presented in Table 2. The reduction of pressure was measured in comparison with the pressure when the channel does not comprise a fractioning device. The separation factor is calculated as the ratio of the pressure as initially set in the second chamber and the pressure reached in the first chamber. It indicates the effectiveness of the fractioning device.

Observations can be made that increasing the number of walls will assist in reducing the pressure in the first chamber, and so increasing the separation factor, indicating a better vacuum situation and as such, an absence of gaseous species which may be prompted to go upstream, to the ion source.

TABLE 2

| | | L of | | % | Separation |
|---|---|---|---|---|---|
| Number of | Number of | fractioning | | reduction | factor |
| fractioning | compart- | device | Pressure | vs initial | (P. in/ |
| walls | ments | (m) | (10⁻² Pa) | Pressure | P. out) |
| 0 | 1 | 0 | 5.9 | | 8.5 |
| 1 | 2 | 0.14 | 4.7 | 20.3 | 10.6 |
| 2 | 4 | 0.28 | 4.0 | 32.2 | 12.5 |
| 3 | 6 | 0.38 | 3.5 | 40.7 | 14.3 |
| 4 | 8 | 0.48 | 3.2 | 45.8 | 15.6 |

### Example 2

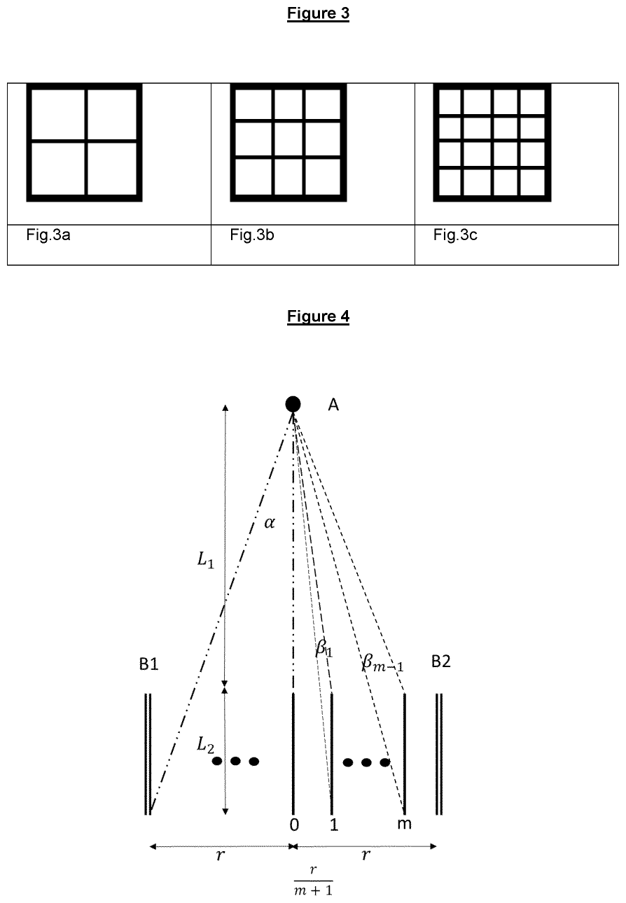

A configuration featuring a second chamber (a processing chamber), a first chamber (an ion source chamber) and a channel connecting the two chambers were designed. The inner section of the channel was of square shape with fractioning walls parallel to the sides of the square (FIG. 3, a to c). The number of fractioning walls was varied to indicate impact on the pressure. The channel's inner dimensions were 0.58×0.062×0.062 m³, and internal perimeter of 0.248 m (=4×0.062 m). The channel was provided with 3 pumps, operated at a total pumping speed of 500 l/s (pump 1: 400 l/s; pump 2: 50 l/s; pump 3: 50 l/s).

The second chamber was set at a pressure of 6×10⁻² Pa, and the pressure in the first chamber was measured, with a pump operated at a pumping speed of 250 l/s.

The reduction of pressure is presented in Table 3. The reduction of pressure was measured in comparison with the pressure when the channel does not comprise a fractioning device. The separation factor is calculated as the ratio of the pressure as initially set in a second chamber and the pressure reached in the first chamber. It indicates the effectiveness of the fractioning device.

Increasing the number of walls assists in reducing the pressure in the first chamber, and so increasing the separation factor. That is, for a same pump in the first chamber, the efficiency is increased, and pressure is significantly reduced. The presence of the undesired species is limited or eliminated.

TABLE 3

| | | L of | | % | Separation |
|---|---|---|---|---|---|
| Number of | Number of | fractioning | | reduction | factor |
| fractioning | compart- | device | Pressure | vs initial | (P. in/ |
| wall(s) | ments | (m) | (10⁻⁴ Pa) | Pressure | P. out) |
| 0 | 1 | 0 | 82.8 | | 7.24 |
| 2 - FIG. 3a | 4 | 0.124 | 51 | 38.4 | 11.8 |
| 4 - FIG. 3b | 9 | 0.248 | 35 | 57.7 | 17.1 |
| 6 - FIG. 3c | 16 | 0.372 | 25.8 | 68.8 | 23.3 |

### Example 3

Example 2 was repeated, this time with a configuration where the channel's inner dimension was 0.58×0.01×0.01 m³, and internal perimeter of 0.04 m (=4×0.01 m). Results are indicated in Table 4.

Pressure is significantly reduced upon the increasing number of fractioning walls, while the separation factor also increases.

TABLE 4

| | | L of | | % | Separation |
|---|---|---|---|---|---|
| Number of | Number of | fractioning | | reduction | factor |
| fractioning | compart- | device | Pressure | vs initial | (P. in/ |
| wall(s) | ments | (m) | (10⁻⁷ Pa) | Pressure | P. out) |
| 0 | 1 | 0 | 15.1 | | 0.4 10e5 |
| 2 - FIG. 3a | 4 | 0.02 | 4.5 | 70.2 | 1.3 10e5 |
| 4 - FIG. 3b | 9 | 0.04 | 3.5 | 76.8 | 1.7 10e5 |
| 6 - FIG. 3c | 16 | 0.06 | 2.0 | 86.8 | 3.0 10e5 |

### Examples 5 to 9 and Comparative Example 4

Comparative example 4 and Examples 5 to 9 provide for calculations of useful angle θ and conductance based on the number of fractioning walls, using the formulae I, II and Ill discussed above. Results are indicated in Table 5.

TABLE 5

| | Number of | Number of | Useful | Conductance |
|---|---|---|---|---|
| | fractioning | compart- | angle | (arbitrary |
| | wall(s) | ments | (°) | units) |
| Comparative | 0 | 1 | 24.19 | 1 |
| Example 4 | | | | |
| Example 5 | 1 | 2 | 24.19 | 0.500 |
| Example 6 | 2 | 3 | — | 0.333 |
| Example 7 | 3 | 4 | 19.36 | 0.250 |
| Example 8 | 4 | 5 | — | 0.200 |
| Example 9 | 5 | 6 | 14.58 | 0.0167 |

Example 7 provides the optimal conditions for the compromise between the number of fractioning walls in the fractioning device, with regard to the conductance reduction and the useful angle. Example 9 provides for a greater conductance reduction, with a smaller useful angle.

### Example 10 and Comparative Example 1

In an initial configuration where the channel has a square section (10×10 cm²) and a length of 5 m, a fractioning device having 2 fractioning walls may reduce the length of the channel by half, while having the same pressure ratio and the same pumping efficiency. For a pumping rate of 1 m³/s and a pressure ratio p1/p2˜30, the conductance will be impacted by the presence of fractioning walls within the channel, impacting the length of the channel, as indicated in Table 6.

(pumping rate (m³/s)=conductance (m³/s)×((p1/p2)−1))

TABLE 6

| | | | Channel |
|---|---|---|---|
| | Fractioning | Conductance | length |
| | walls | (m³/s) | (m) |
| CE 1 | 0 | C1 = 0.0343 | 5 |
| Example 10 | 2 | C½ = 0.0172 | 2.5 |

### Example 11 and Comparative Example 2

Ion implantation was carried out using an ECR ion source, into a processing chamber containing samples of soda-lime glass of 1.1 mm thickness, in sample sizes of 20×20 cm². The ion implantation conditions comprised a voltage of 20 kV, using nitrogen, at a dose of 9×10¹⁶ ion/cm². The pressure in the ion source was greater than the pressure in the processing chamber (p1>p2).

Comparative Example 2 (CE2): the ion implantation occurred in absence of any fractioning device, with the channel connecting the ion source and the processing chamber housing the substrates. The channel has an internal diameter of 0.10 m, fora perimeter of 0.314 m.

Example 11: The fractioning device consisted in a conical internal shape, with the small section of the cone towards the ion source and the large section of the cone towards the processing chamber, complemented with two fractioning walls, having an intersection in the middle of the cross-section of said channel, having a length 50% of the channel, protruding into the processing chamber for 0.05 m. The average transversal cross-sectional length (ATCSL) of the fractioning device, takes into account the average perimeter of the conical shape (0.20 m), and the average transversal cross-sectional length of the fractioning walls (2×0.04 m), such that the ATCSL=0.28 m.

Results are presented in Table 7, comparing the impact of the fractioning device on pressure control between the ion source and the processing chamber, and indicating the pressure differential is increasing with the presence of the fractioning walls.

Also provided is the measure of light reflection from the implanted glass side, indicating charges were neutralized such that implantation could occur according to the intended dose. The lower reflectance of Example 11 indicates the implanted dose (the same as for Comparative example 2) reaches the substrate as intended. There is no barrier to implantation due to charge build-up at the surface of the substrate, in the presence of the fractioning device.

TABLE 7

| | Number of | Number of | Pressure | |
|---|---|---|---|---|
| | fractioning | compart- | difference | |
| | wall(s) | ments | (10⁻⁵ Pa) | RL |
| CE2 | 0 | 1 | 4.93 | 5.93 |
| Ex11 | 2 | 4 | 12.00 | 4.96 |

It was noted, that despite the obstacle that the fractioning device may represent, there is no loss of current and no loss of the initial energy of the ion beam.

The fractioning device, by its charge neutralizing effect, allows for implantation of the dose as intended, without arc or loss of power of the ion beam onto the substrate.

A similar effect may be observed on boro-silicate glass, and on sapphire.

1. A fractioning device for an ion implantation device comprising:
at least one fractioning wall,
wherein the fractioning device is suitable for being inserted within a channel,
wherein the channel is configured to connect an ion source and a processing chamber,
wherein the ion source is at a first pressure (p1) and the processing chamber is at a second pressure (p2), and
wherein an average transversal cross-sectional length of the fractioning device is at least 10% of an internal perimeter of the fractioning device.

2. The fractioning device of claim 1, wherein a length of the fractioning device is not more than 80% of the length of the channel.

3. The fractioning device of claim 1, wherein at least one valve is configured between the channel and the ion chamber.

4. The fractioning device of claim 1, wherein the fractioning device comprises two or more fractioning walls.

5. The fractioning device of claim 4, wherein the two or more fractioning walls intersect at least at one point.

6. The fractioning device of claim 4, wherein the two or more fractioning walls do not intersect.

7. The fractioning device of claim 1, wherein the fractioning device is placed at any distance from a center point of an internal section of the channel and/or placed at any height inside the channel.

8. The fractioning device of claim 1, wherein the fractioning device comprises a material selected from the group consisting of graphite, stainless steel, boron carbide, silicon oxide, silicon carbide, silicon nitride, aluminium carbide, zirconium oxide, zirconium carbide, titanium oxide, titanium carbide, molybdenum oxide, molybdenum carbide, niobium oxide, niobium carbide, yttrium oxide, yttrium carbide, magnesium oxide, tin oxide, ceramic, tungsten carbide, tungsten oxide, hafnium oxide, tantalum oxide, carbon, chromium carbide and combinations of these materials.

9. The fractioning device of claim 8, wherein the material of the fractioning device has a sputtering reduction coating.

10. The fractioning device of claim 1, wherein a minimum acceleration voltage is 15 kV.

11. An ion implantation device comprising:
an ion source configured to be operated at a first pressure (p1) suitable for generating an ion beam,
a processing chamber configured to be operated at a second pressure (p2) suitable for housing a substrate,
a channel configured to connect the ion source and the processing chamber,
wherein the channel is configured to have an internal cross-section and to allow the passage of the ion beam within the internal cross-section, and
wherein the channel comprises at least one fractioning device according to claim 1 within its internal cross-section along at least part of the length of the internal cross-section.

12. The ion implantation device of claim 11, wherein the first pressure is less than the second pressure.

13. The ion implantation device of claim 11, wherein the first pressure is greater than the second pressure.

14. The ion implantation device of claim 11, wherein the channel comprises one or more fractioning devices at different positions within the channel.

15. The ion implantation device of any of claim 11, wherein the ion source in an Electron Cyclotron Resonance ion source.

16. The ion implantation device of claim 11, wherein the channel comprises at least one vacuum pump.

17. A process for ion implantation on a substrate comprising the steps of:
providing for a substrate,
providing for an ion implantation device according to claim 11,
proceeding to the ion implantation of the substrate.

18. (canceled)

19. (canceled)

20. The fractioning device of claim 1, wherein at least one valve is configured between the channel and the processing chamber.
